(19) United States
(12) Patent Application Publication
(10) Pub. No.: US 2009/0220872 A1
(43) Pub. Date: Sep. 3, 2009

(54) DETECTING APPARATUS, EXPOSURE APPARATUS, AND DEVICE MANUFACTURING METHOD

(75) Inventor: Satoru Oishi, Utsunomiya-shi (JP)

Correspondence Address: CANON U.S.A. INC. INTELLECTUAL PROPERTY DIVISION, 15975 ALTON PARKWAY, IRVINE, CA, 92618-3731, US

(73) Assignee: CANON KABUSHIKI KAISHA, Tokyo (JP)

(21) Appl. No.: 12/393,982

(22) Filed: Feb. 26, 2009

(30) Foreign Application Priority Data
Feb. 29, 2008 (JP) 2008-050128

(51) Int. Cl. G03B 27/58; G03F 7/20

(52) U.S. Cl. 430/30; 355/72

(57) ABSTRACT

A detecting apparatus includes a image pickup device configured to supply an output signal, an imaging optical system configured to form an image of an alignment mark formed on a substrate onto the image pickup device, and a signal processing unit including a restoration filter having a parameter that can be set, and configured to process the output signal and detect a position of the alignment mark, wherein the signal processing unit is configured to cause the restoration filter to act upon the output signal and generate a restoration signal, compute based on the restoration signal, for each of a plurality of candidate values of the parameter, a corresponding feature value relating to a form of the alignment mark, and set the parameter based on the computed feature values.

### BACKGROUND OF THE INVENTION

1. Field of the Invention

The present invention relates to a detecting apparatus to detect the position of an alignment mark formed on a base.

2. Description of the Related Art

With a semiconductor exposure apparatus, in accordance with higher functionality and lower prices of electronic devices in recent years, the manufacturing of the semiconductors built therein also require not only high precision but also efficient production. Additionally, high precision and efficient manufacturing of exposure apparatuses to expose circuit patterns of the semiconductor is requested. With an exposure device that generates a semiconductor, a process is performed to transfer a circuit pattern formed on a reticle, mask, or the like (hereafter called “reticle”) onto a wafer, glass plate, or the like (hereafter called “wafer”) whereupon a photosensitive material (hereafter called “resist”) is coated. Generally, in order to transfer the circuit pattern with high accuracy, a mutual positioning (alignment) of the reticle and wafer becomes necessary.

With an alignment according to related art, at the same time as the exposure transfer of the circuit pattern onto the reticle, an alignment mark is made by exposure transfer onto the wafer. The position of the alignment mark with multiple shots set beforehand from all shots is sequentially detected via an alignment detecting optical system. Based on the position detecting results thereof, an array of all shots is computed, and based on the computing results thereof the positioning of the wafer as to the reticle is determined.

The alignment mark is an index to align the reticle and wafer with high precision, and in accordance with the miniaturization of circuit patterns, miniaturization is also becoming required of alignment marks. Also, in recent years, semiconductor manufacturing techniques such as CMP (Chemical Mechanical Polishing) have been introduced. With CMP, the form of alignment marks between wafers or between shots scatters, whereby position detection error resulting from the wafer process (WIS: Wafer Induced Shift) occurs, thereby causing the alignment precision to deteriorate. In other related art, WIS is reduced with an offset calibration (see Japanese Patent Laid-Open No. 2004-117030). “Offset calibration” computes an offset amount which is a shift amount between the position where the alignment mark originally should have been and the position of the alignment mark actually detected by the detection system, and corrects the detected position based on the offset amount thereof.

However, the reason for such position detecting error is not only error resulting from the wafer process (WIS). For example, error resulting from an exposure apparatus (alignment detecting system) (TIS: Tool Induced Shift) or error resulting from the interaction between TIS and WIS (TIS-WIS Interaction) can cause the alignment precision to deteriorate. Reasons for WIS may include step dimension of the alignment marks, asymmetry, and uneven resist coating. Reasons for TIS may be comatic aberration or spherical aberration of the alignment detecting system.

Recently, alignment detecting systems have had high NA (numerical aperture), but TIS cannot be completely made zero. Therefore, with the TIS-WIS interaction, in the case that there is WIS (e.g. low level marks or uneven resist coating, etc) position detecting of the alignment marks may not be highly precise. Referencing FIGS. 24A and 24B, even if the optical system is the same, since there is TIS, the position detecting error with a low step dimension alignment mark as shown in FIG. 24B is greater than a position detecting error with a normal step dimension alignment mark as shown in FIG. 24A.

If we say that an observation signal is g, the optical system transfer characteristic is h, input signal is f, and noise is n, as shown in FIG. 25, in the case that the optical system is linear and shift-invariant, the observation signal g is expressed as in Expression 1. Note that device resulting errors (TIS) are included in the transfer characteristic h of the optical system.

$$\begin{matrix}\begin{matrix}g ( x ) = f ( x ) ⋆ h ( x ) + n ( x ) \\ = {\int }_{- ∞}^{∞} h ( τ ) \cdot f ( x - τ ) d τ + n ( x )\end{matrix} & ( Expression 1 )\end{matrix}$$

Japanese Patent Laid-Open No. 2007-273634 proposes a technique to restore the input signal f from the observation signal g, using the transfer characteristic h from the optical system and a restoration filter such as a Wiener filter. The influence of TIS in the restored input signal becomes infinitely small, so reducing the position detecting error from TIS-WIS interaction can be expected. Expression 2 and Expression 3 show the restoration method using a Wiener filter.

$$\begin{matrix}{f}^{′} = {FT}^{- 1} [ FT ( g ) \times K ] & ( Expression 2 ) \\ K = \frac{{FT ( h )}^{⋆}}{{\vert FT ( h ) \vert}^{2} + Sn / Sf} = \frac{{FT ( h )}^{⋆}}{{\vert FT ( h ) \vert}^{2} + γ} & ( Expression 3 )\end{matrix}$$

Now, f′ denotes the restored input signal, K the Wiener filter, Sn the power spectrum of noise n, Sf the power spectrum of input signal f, and γ (=Sn/Sf) the restored parameter. Also, FT expresses a Fourier transform, FT-1 an inverse Fourier transform, and * a complex conjugate.

However, in the case of performing restoration using the above-mentioned Wiener filter, the input signal and noise power spectrum is unknown in most cases, and in related art the restoration parameter γ has assigned an arbitrary fixed value regardless of the frequency, or assigned an arbitrary value for each frequency. However, this parameter is not necessarily optimal, and there has been room for improvement.

### SUMMARY OF THE INVENTION

The present invention has been made with consideration for the above-described problems, and provides for appropriately setting parameter values for a restoration filter.

According to an aspect of the present invention, a detecting apparatus includes a image pickup device configured to supply an output signal, an imaging optical system configured to form an image of an alignment mark formed on a substrate onto the image pickup device, and a signal processing unit including a restoration filter having a parameter that can be set, and configured to process the output signal and detect a position of the alignment mark, wherein the signal processing unit is configured to cause the restoration filter to act upon the output signal and generate a restoration signal, compute based on the restoration signal, for each of a plurality of candidate values of the parameter, a corresponding feature value relating to a form of the alignment mark, and set the parameter based on the computed feature values. According to another aspect of the present invention, an exposure apparatus includes a substrate stage configured to hold a substrate and to be moved, a controller configured to control the position of the substrate stage based on a position of at least one alignment mark formed on the substrate held by the substrate stage, the exposure apparatus exposing the substrate, held by the substrate stage of which position is controlled by the controller, to radiant energy, and a detecting apparatus defined as above and configured to detect the position of the at least one alignment mark.

According to another aspect of the present invention, a method of manufacturing a device includes exposing a substrate to radiant energy using an exposure apparatus defined as above, developing the exposed substrate, and processing the developed substrate to manufacture the device.

According to another aspect of the present invention, parameter values for the restoration filter can be appropriately set.

Further features of the present invention will become apparent from the following description of exemplary embodiments with reference to the attached drawings. Other objects and advantages besides those discussed above shall be apparent to those skilled in the art from the following description of exemplary embodiments of the present invention.

### BRIEF DESCRIPTION OF THE DRAWINGS

The accompanying drawings, which are incorporated in and constitute a part of the specification, illustrate embodiments of the invention and, together with the description, serve to explain the principles of the invention.

FIG. 1 is a flowchart describing a first embodiment of the present invention.

FIG. 2 is a diagram illustrating an exposure apparatus.

FIG. 3 is a diagram describing an alignment detecting system.

FIGS. 4A and 4B are a plan view and cross-sectional diagram illustrating an alignment mark.

FIGS. 5A and 5B are a plan view and cross-sectional diagram illustrating an alignment mark.

FIG. 6 is a diagram illustrating a detecting signal of an alignment mark.

FIG. 7 is a diagram illustrating a function module within a signal processing unit.

FIG. 8 is a plan view of a sandwiching mark.

FIGS. 9A and 9B are diagrams illustrating a transfer characteristic measuring mark.

FIG. 10 is a plan view illustrating a transfer characteristic measuring mark.

FIGS. 11A through 11C are diagrams illustrating details of a sandwiching mark.

FIGS. 12A through 12C are explanatory diagrams relating to settings of a restoration parameter.

FIG. 13 is a flow diagram describing a second embodiment of the present invention.

FIGS. 14A through 14C are explanatory diagrams relating to settings of a restoration parameter according to the second embodiment.

FIGS. 15A and 15B are diagrams illustrating a sandwiching mark according to a third embodiment of the present invention.

FIG. 16 is a flowchart describing the third embodiment.

FIG. 17 is a diagram illustrating a sandwiching mark according to a fourth embodiment of the present invention.

FIG. 18 is a flowchart describing the fourth embodiment.

FIGS. 19A and 19B are diagrams describing a fifth embodiment of the present invention.

FIGS. 20A and 20B are diagrams describing a sixth embodiment of the present invention.

FIGS. 21A and 21B are diagrams describing a seventh embodiment of the present invention.

FIGS. 22A and 22B are diagrams describing an eighth embodiment of the present invention.

FIGS. 23A and 23B are diagrams describing a ninth embodiment of the present invention.

FIGS. 24A and 24B are diagrams illustrating an offset amount by TIS-WIS interaction.

FIG. 25 is a diagram illustrating input/output relation of a linear system.

FIGS. 26A and 26B are explanatory diagrams relating to mark (element) position detecting.

FIG. 27 is a diagram describing distortion of a signal waveform.

FIGS. 28A through 28C are diagrams exemplifying an M-series signal, wherein FIG. 28A illustrates an input signal, FIG. 28B an output signal, and FIG. 28C transfer characteristics.

### DESCRIPTION OF THE EMBODIMENTS

Various embodiments of the present invention are described below with reference to the drawings. In the following description and the various figures, except if noted otherwise, each instance of a reference mark refers to the same item.

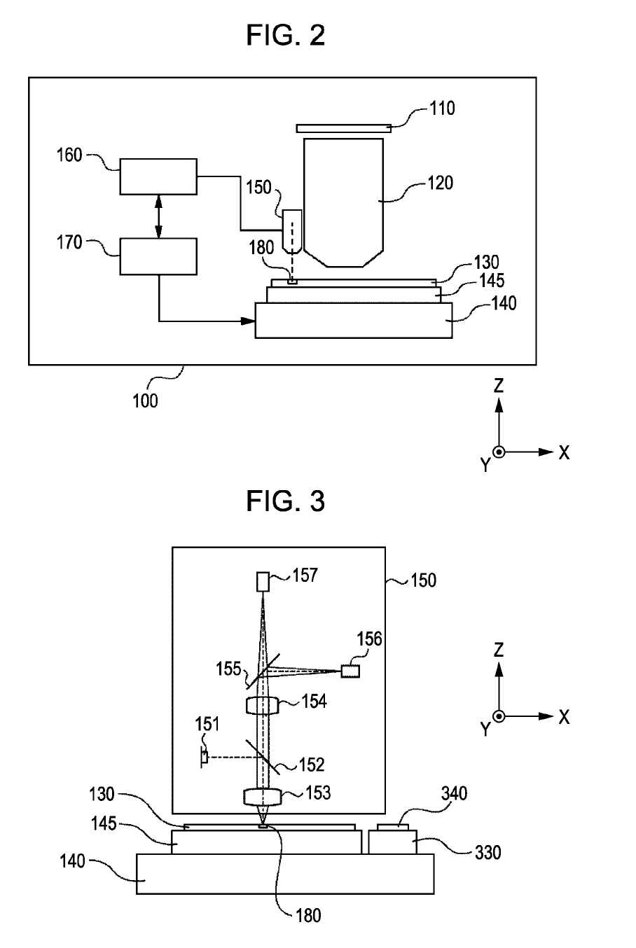

FIG. 2 is a schematic block diagram illustrating an example of an exposure apparatus 100. The exposure apparatus 100 is a projection exposure apparatus that exposes a wafer via a circuit pattern formed on a reticle with a step-and-scan method or step-and-repeat method. A projection exposure apparatus is favorable for a lithography process wherein the line width is a submicron or less. The “step-and-scan method” is an exposure method which continuously scans a wafer as to a reticle and exposes the wafer via the reticle pattern, and after ending exposure of one shot, step-moves the wafer to the next exposure region. The “step-and-repeat method” is an exposure method to step-move the wafer for each single exposure of the wafer and moves to the next exposure region.

In FIG. 2, the exposure apparatus 100 has a projection optical system 120, wafer chuck 145, wafer stage apparatus (also called substrate stage) 140, alignment detecting system 150, alignment signal processing unit (also simply called signal processing unit) 160, and control unit 170. The projection optical system 120 subjects the reticle 110 whereupon a pattern such as a circuit pattern is drawn to reduced projection. The wafer chuck 145 holds the wafer 130 whereupon a base pattern and alignment mark 180 has been formed in the previous process. The wafer stage apparatus 140 positions the wafer 130 at a predetermined position. The alignment detecting system 150 measures the position of the alignment mark 180 on the wafer 130. An illumination optical system is used to illuminate the reticle 110 using light from a light source (not shown).

The control unit 170 has an unshown CPU and memory, and controls the operation of the exposure apparatus 100. The control unit 170 is electrically connected to an unshown illumination apparatus, an unshown reticle stage apparatus, wafer stage apparatus 140, and alignment signal processing unit 160. The control unit 170 performs positioning of the wafer 130 via the wafer stage apparatus 140, based on alignment mark position information from the alignment signal processing unit 160.

Next, detection principles of the alignment mark 180 will be described. FIG. 3 is an optical path diagram illustrating primary configuration elements of the alignment detecting system 150. Referencing FIG. 3, illumination light from the alignment light source 151 is reflected with a beam splitter 152, passes through an object lens 153, and illuminates the alignment mark 180 on the wafer 130. The light from the alignment mark 180 (reflected light, diffracted light) passes through the object lens 153, beam splitter 152, and lens 154, is divided with the beam splitter 155, and is received by sensors (image pickup devices) 156 and 157 such as a CCD. Now, 153 through 155 make up an imaging optical system that forms an image of the alignment mark formed on the wafer (substrate) 130 onto an image pickup device.

The alignment mark 180 is enlarged to an imaging magnification of roughly 300 times by the lens 153 and 154, and is imaged onto the imaging sensors 156 and 157. The sensors 156 and 157 are shift-measurement sensors for the X-direction and Y-direction of the alignment mark 180, respectively, and are set so as to be rotated 90 degrees as to the light axis. A line sensor may be used for the imaging sensors 156 and 157. In this case, a cylindrical lens having power only in the direction perpendicular to the measurement direction may be used to condense the light in the perpendicular direction and integrate (average) optically. The measurement principles are similar in the X-direction and y-direction, so the position measurement of the X-direction will be described here.

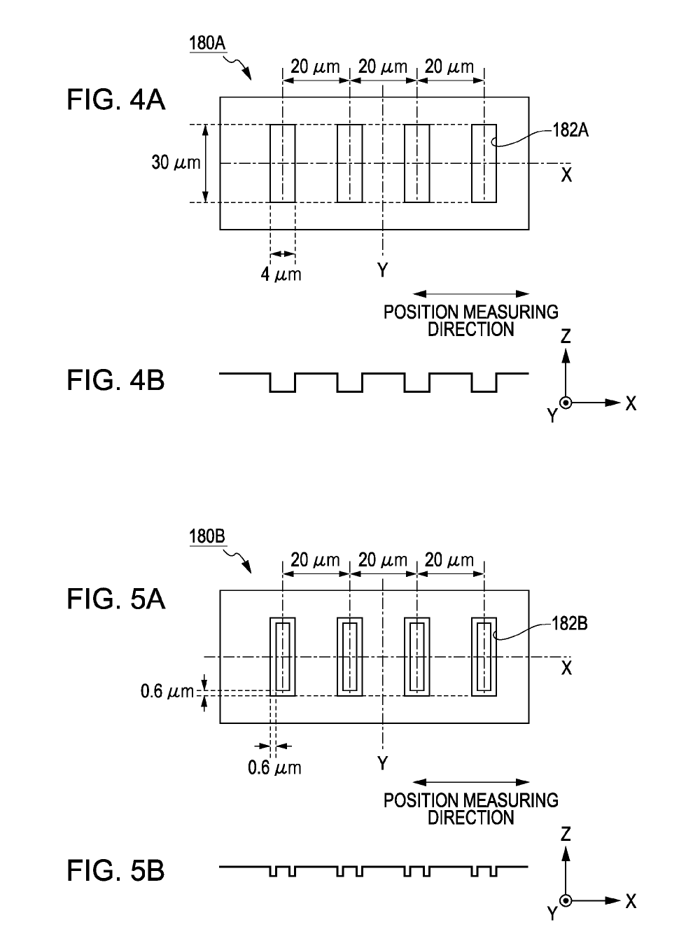

The alignment mark 180 is disposed on a scribe-line for each shot, and for example, alignment marks 180A and 180B in the forms shown in FIGS. 4A, 4B, 5A, and 5B can be used. Note that the alignment mark 180 is a generalization of the alignment marks 180A and 180B. FIGS. 4A and 4B illustrate a plan view and cross-sectional view of the alignment mark 180A, and FIGS. 5A and 5B illustrate a plan view and cross-sectional view of the alignment mark 180B. In FIGS. 4A through 5B, the alignment mark 180A and 180B include four mark elements 182A and 182B disposed at equal spacing. A resist (not shown) is coated on the alignment marks 180A and 180B.

With the alignment mark 180A, four mark elements 182A are lined up in a rectangular shape as shown in FIG. 4A, at a pitch of 4 μm in the X-direction which is the measurement directions and 20 μm in the Y-direction which is the non-measurement direction. The cross-sectional configurations of the mark elements 182A have a concave shape, as shown in FIG. 4B. On the other hand, with the alignment mark 180B, as shown in FIGS. 5A and 5B, four mark elements 182B which replace the outline portion of the mark element 182A in FIGS. 4A and 4B are replaced with a line width of 0.6 μm.

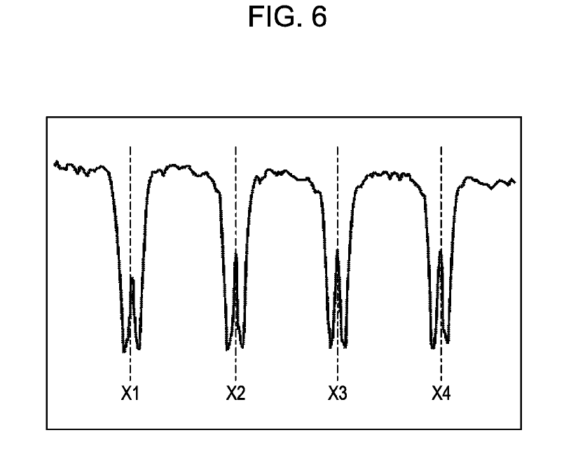

FIG. 6 is a graph showing typical results of the alignment marks 180A and 180B shown in FIGS. 4A through 5B that are optically detected and imaged with a sensor 156. The optical image obtained in FIG. 6 generally has high frequency components cut at the edge portions of the alignment marks. Regardless of which alignment mark 180A or 180B is used, scattered light occurs at the edge portions of a large angle not fitting into the NA of the lens 153 and 154 of the alignment detecting system 150. Therefore, not all signals from the alignment mark pass through the alignment detecting system 150. Thus, with the alignment detecting system 150, deterioration of information occurs, and the high frequency components are attenuated. Border portions of the alignment mark 180A are dark, and concave portions of the alignment mark 180B are dark or light when the alignment mark 180A is illuminated under bright-field illumination. An image of the alignment mark 180 thus imaged is subject to alignment signal processing via the alignment signal processing unit 160.

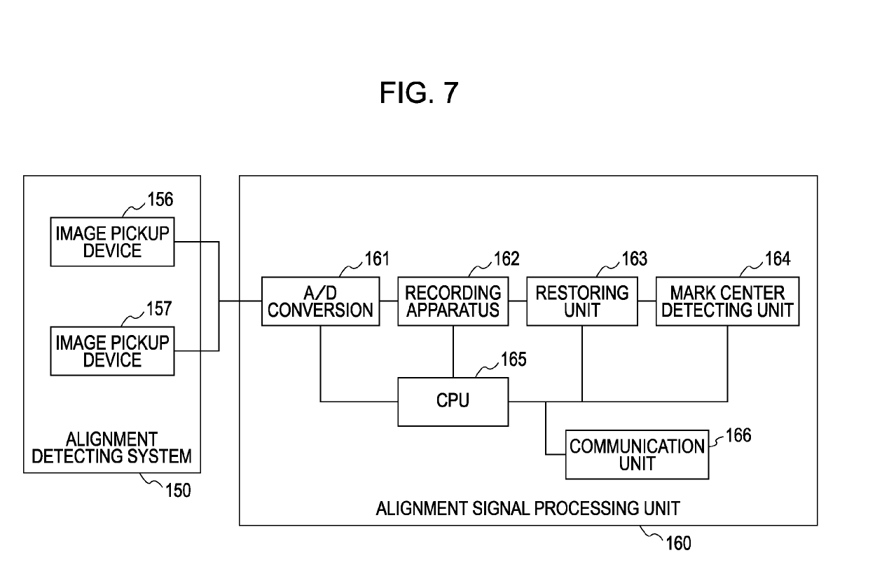

FIG. 7 is a block diagram showing primary function modules built into the alignment signal processing unit (also simply called signal processing unit) 160. A detecting apparatus that detects the position of the alignment marks is composed of the alignment detecting system 150 and the signal processing unit 160. The alignment detecting system 150 includes the image pickup devices 156 and 157 and the imaging optical system (153 through 155).

Referencing FIG. 7, the alignment signal from the imaging sensor 156 and 157 are digitized through an A/D converter 161. The digitized alignment signals are recorded in the memory built into the recording device 162. The restoring unit 163 performs TIS correction (restoring processing) as to the output signal of the alignment mark that is deteriorated through the alignment detecting system recorded in the recording apparatus 162. In this event, the later-described restoring processing is performed, using transfer characteristic h(x) which is computed with the control unit 170 in FIG. 2.

Next, the mark center detecting unit 164 performs digital signal processing as to the restored alignment signal, and detects the center position of the alignment mark. The CPU 165 is connected to an A/D converter 161, recording apparatus 162, restoring unit 163, mark center detecting unit 164, and outputs control signals to perform operation controls. A communication unit 166 performs communication with the control unit 170 shown in FIG. 2, and exchanges necessary data, control commands, and so forth.

The digital signal processing performed with the mark center detecting unit 164 may include, for example, one of more of a method to detect the edge portions of the alignment signal and calculate the edge positions, a pattern matching method using a template, and a symmetry matching method. The symmetry matching method may be implemented, for example, using technology described in Japanese Patent Laid-Open No. 2007-273634 published Oct. 18, 2007 and United States Patent Application Publication No. US 2007/0237253 A1 published Oct. 11, 2007, each which is hereby incorporated by reference herein in its entirety.

Output from the signal source may be a two-dimensional image signal or a one-dimensional image signal. A two-dimensional image can be converted into a one-dimensional image by creating a histogram of the pixels in the horizontal direction of the two-dimensional signal in the vertical direction, performing image voting processing to average across primary components. In the case of the digital signal processing proposed with the present invention, the measurements of the X-direction and the Y-direction are independently configured, so the signal processing to be the basis for positioning is determined with the one-dimensional signal processing. For example, a two-dimensional image on the image-pickup sensors 156 and 157 is integrated with a digital signal and subject to averaging, and converted into a one-dimensional line signal.

Performing signal restoring of the present invention is not limited to the restoring unit 163 in FIG. 7. For example, the signal restoring of the present invention may be performed with the CPU 165 of the alignment signal processing unit 160 in FIG. 7, or may be performed with software outside of the exposure apparatus.

Also, the present invention is not limited to restoring the alignment mark signal, and for example, the present invention can be applied to various types of measuring marks, such as marks for an overlay inspection apparatus.

Next, a mark (also called “sandwiching mark”) for determining (also called “setting”) the value of a restoring parameter (also simply called “parameter”) according to the present embodiment will be described.

A sandwiching mark 350 for determining a restoring parameter according to the present embodiment is made up with a mark having a changed level with Si wafer etching processing.

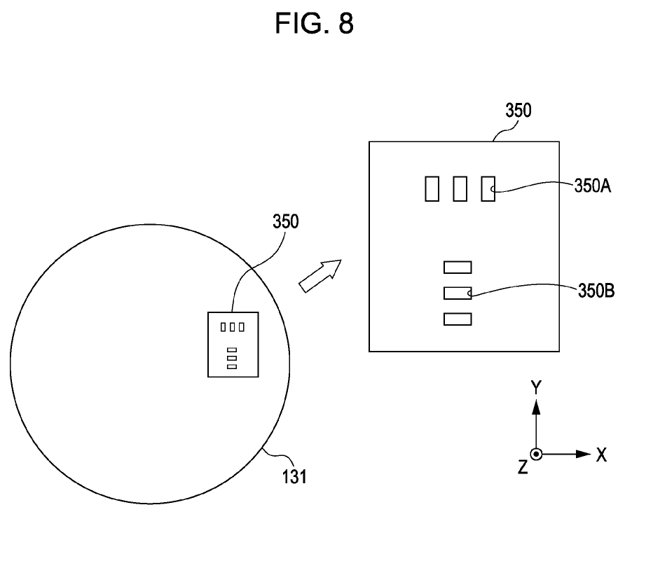

FIG. 8 is a plan view schematic diagram of the sandwiching mark 350, and the sandwiching mark 350 for determining the restoring parameters are created on the Si wafer 131 instead of the wafer 130 in FIG. 3. Reflected light from these sandwiching marks 350 are imaged with the alignment detecting system 150, and similar to the alignment marks on the wafers, light is received with imaging sensors 156 and 157 such as a CCD. The sandwiching mark for measuring in the X-direction is 350A, and the sandwiching mark for measuring in the Y-direction is 350B.

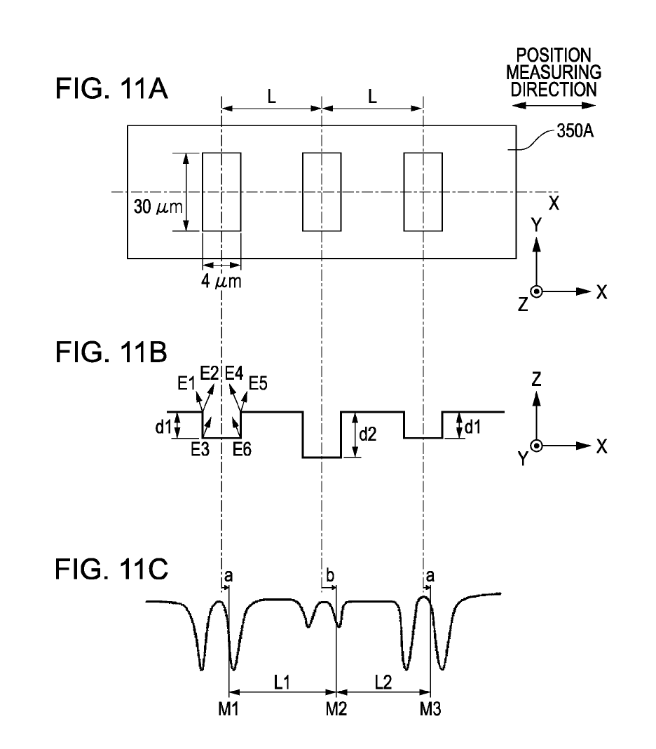

Next, details of the sandwiching mark 350 will be described with reference to FIGS. 11A through 11C. FIG. 11A shows a plan view of a sandwiching mark 350A. The plan view shape of the sandwiching mark according to the present embodiment has the same plan view shape as the alignment mark 180. In FIG. 11A, for example, similar to the alignment mark 180A, the width in the X-direction is 4 μm and the width in the Y-direction is 30 μm.

Also, FIG. 11B shows a cross-sectional view of the sandwiching mark 350A. The step dimension on the outer side of the sandwiching mark 350A is d1=200 nm and the step dimension on the inner side thereof is d2=300 nm. In FIG. 11B, as the scattered light from the mark edge, let the light from the left edge upper portion be represented by E1 and E2, the light from the left edge lower portion be represented by E3, light from the right edge upper portion be represented by E4 and E5, and the light from the right edge lower portion be represented by E6. The light intensity changes with interference of the light E2 from the edge upper portion and the light E3 of the lower portion in accordance with the step dimension d, and the intensity of the scattered light E1 and E2 from the same edge also changes according to influence from comatic aberration.

Now, it is desirable to set selecting the two step dimensions d1 and d2 of the sandwiching mark 350A such that the difference in shift amounts of the light intensity signal obtained on the CCD influenced by comatic aberration of the optical system (position shift from the mark center) is great. Generally, the signal with a low control of light intensity signal is considered to have a greater shift amount from the same comatic aberration than does a high signal.

Accordingly, selecting step dimensions d1 and d2 is more desirable, so as to have a large shift amount difference and thus includes a combination of low contrast mark elements and high contrast mark elements. A step dimension with low contrast is, for example, d=λ/2 where the illuminating wavelength is λ, and according to the present embodiment, the illuminating wavelength is λ=600 nm, the step dimension having low contrast is d2=300 nm, and the step dimension having high contrast is d1=200 nm. The relation between the step dimension and contrast is calculated with an optical simulation based on structural birefringence. Further, setting the difference between d1 and d2 (100 nm) with consideration for the size of variance from the wafer process is desirable.

FIG. 11C shows an example of a signal wave of the sandwiching mark 350A. The mark positions obtained by later-described signal processing of the sandwiching mark 350A is, sequentially from the left, M1, M2, and M3, and the spacing thereof is L1=M2−M1, L2=M3−M2. Further, where the shift amount in M1 is a, the shift amount in M2 is b, and the design value of mark position spacing is L, the following relationship holds.

L1=M2−M1=L−a+b

L2=M3−M2=L+a−b

The difference L2−L1 of the mark position spacing becomes L2−L1=2 (a−b).

Accordingly, a restoring parameter wherein the value of a−b becomes small with the restoring signal should be determined.

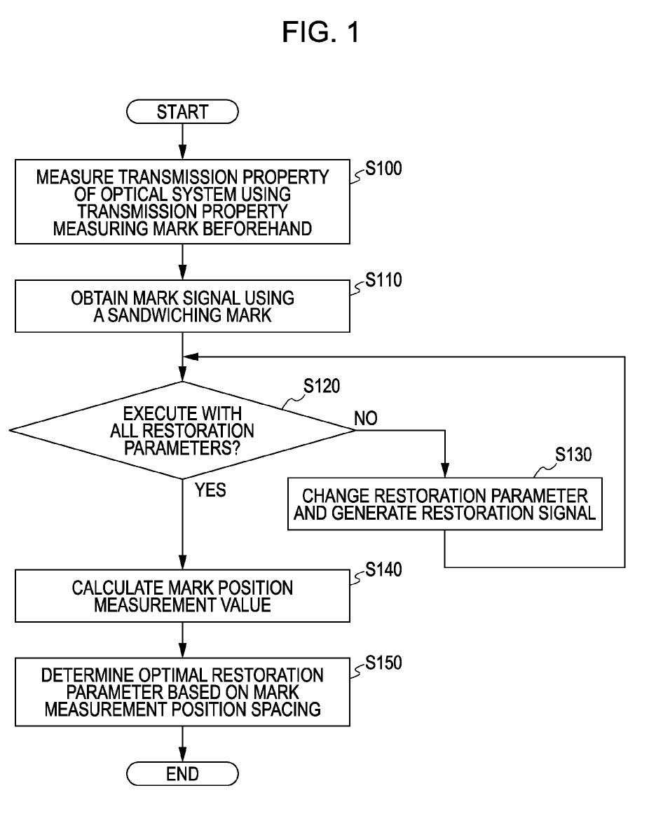

The reason for using a sandwiching mark with the present embodiment is that with the measuring results of one mark, the shift amounts a and b cannot be obtained from a true value such as shown in FIG. 1C. Thus, a sandwiching mark is used to calculate L2−L1, whereby the shift amount difference a−b can be evaluated, and an optimal restoring parameter determined by reducing the a−b.

Even if alignment is performed by the restoring parameter determined with the present embodiment, the shift amount a (b) value itself from the true value is not zero, so consequentially an alignment shift remains. This “shift” can be handled by exposing once and measuring, then offsetting and aligning such portion thereafter.

The above-described L2−L1 is an example of the feature value related to the shape of the alignment marks, and the feature value related to the shape of the alignment mark is not limited to this. For example, the symmetry of one mark (mark element) in the measurement direction, scattering across multiple symmetry mark elements (standard deviation), scattering across multiple mark elements with a mark element width in the measurement direction, and so forth can also be feature values relating to the shape of the alignment mark.

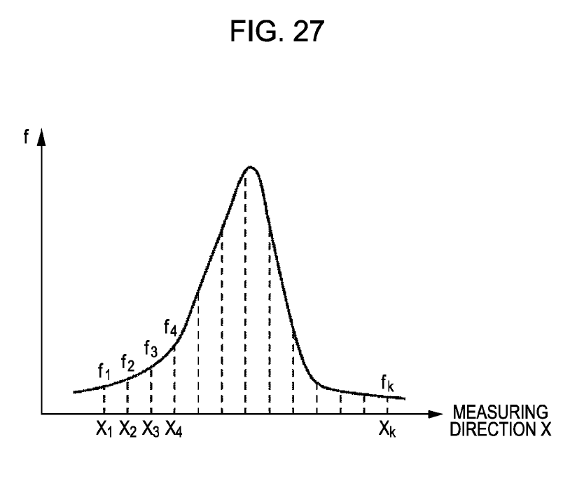

The symmetry of one mark (mark element), as a feature value relating to the shape of the alignment mark, will be described with reference to FIG. 27. With the present invention, skewness, which is generally used as a feature value showing the symmetry of a signal waveform should be applied. Given a signal waveform such as shown in FIG. 27, the skewness can be expressed in Expression 4.

$$skewness = {\sum }_{i = 1}^{k} {{f}_{i} ( {X}_{i} - μ )}^{3} / F {σ}^{3} \qquad ( Expression 4 )$$

where μ is the average distribution of the signal waveform, σ is the standard deviation, and F is the sum of each fi. The skewness herein takes a positive value in the case that the data is skewed from the average toward the right side, and takes a negative value in the case that the data is skewed from the average toward the left side. With the present invention, parameters should be determined so that the skewness from the signal restoring becomes smaller.

Next, a mark 340 for measuring transfer characteristic of the optical system according to the present invention will be described. Referencing FIG. 3, a reference base 330 is disposed on the wafer stage 140, and the mark 340 for measuring the transfer characteristic is disposed on the reference base 330 so as to have the same Z-coordinate position as the wafer 130.

The reflected light from the mark 340 for measuring the transfer characteristic is image-formed with the alignment detecting system 150, and similar to the alignment mark on the wafer, is received on the imaging sensors 156 and 157 such as a CCD.

The mark 340 for measuring the transfer characteristic of the optical system with the present embodiment is a mark drawn on a glass substrate with chrome using an electronic beam exposure apparatus.

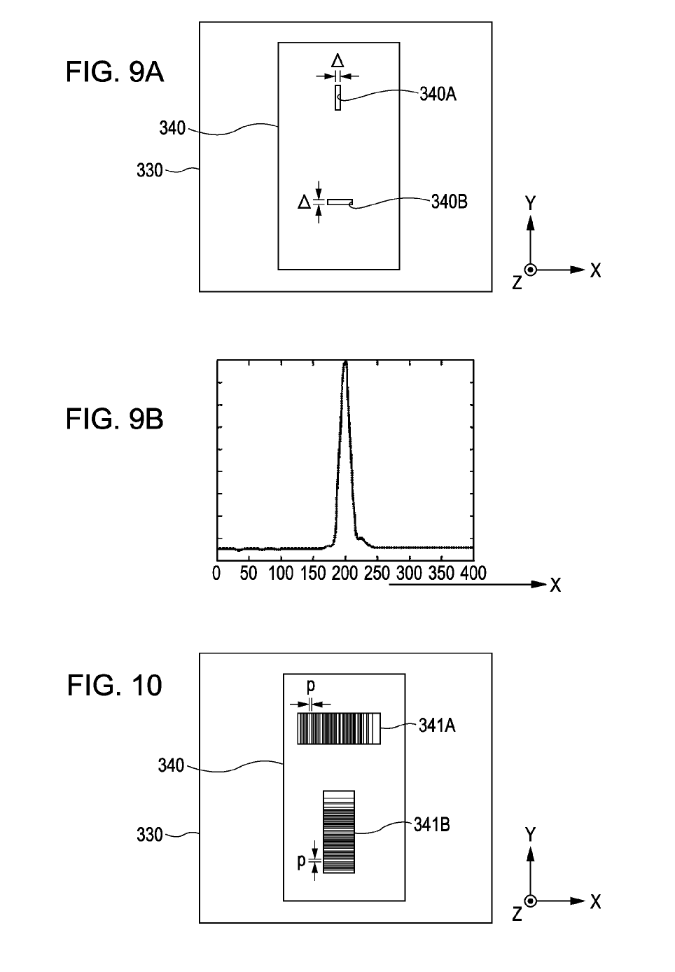

FIG. 9A shows a plan view of the mark 340 for measuring the transfer characteristic on the reference base 330. In FIG. 9A, 340A denotes the mark for measuring the transfer characteristic in the X-direction, and 340B denotes the mark for measuring the transfer characteristic in the Y-direction.

With the present embodiment, the mark for measuring the transfer characteristic is in a minute line form, wherein the portions of 340A and 340B are drawn with chrome, and the other regions are not drawn with chrome but are a glass substrate. The portions drawn with chrome, i.e. 340A and 340B reflect light, and the portion not drawn with chrome absorbs light.

FIG. 9B shows an example of the transfer characteristic measured by the mark 340A for measuring the transfer characteristic in the X-direction. The more minute the line width of the mark 340A or 340B for measuring the transfer characteristic, indicated by triangles in FIG. 9A is, the better, but if the line width is minute to the extreme limits of drawing precision, (e.g. 50 nm or so currently), the light intensity energy becomes small and S/N becomes poor. Therefore, selecting a width between rough 100 nm to 300 nm for example is currently desirable.

In FIGS. 9A and 9B, a minute line is used to measure the transfer characteristic of the optical system, but should not be limited to this, and for example as shown in FIG. 10, an M-series mark can be used as the mark 340 for measuring transfer characteristic. In FIG. 10, 341A denotes the M-series mark for measuring the transfer characteristic in the X-direction, and 341B denotes the M-series mark for measuring the transfer characteristic in the Y-direction.

A method to calculate transfer characteristic from an M-series mark can be obtained as described below, for example. First, the M-series mark is created so that the smallest width in the measurement direction for each of the M-series marks 341A and 341B equate to k pixels in the imaging sensors 156 and 157 on the image side, respectively.

Specifically, is the smallest width of the M-series mark 340 on the physical object side is p, the optical magnification of the imaging optical system 150 is α, and the width of one pixel of the imaging sensors 156 and 157 is c, then the smallest width p of the M-series mark on the physical object side is determined so that

c×k=p×α (Expression 5)

holds, where k is a positive integer.

For example, if k=5, c=8 μm, and a=320, then p=125 nm.

Also, if the effective total number of pixels of the imaging sensors 156 and 157 is N2, and the series length of the M-series mark is N1, the region equating to the M-series mark on the imaging sensor 156 and 157 is K×N1 pixels, which should not exceed the effective total number of pixels of the imaging sensors 156 and 157. Accordingly, satisfying

k×N1<N2 (Expression 6)

becomes a condition thereof. For example, if the effective total number of pixels of the imaging sensors 156 and 157 is 3200, then k<25.

Also, if k is too small, e.g. in the case that k=1, then c=8 μm and α=320 from Expression 5, whereby the smallest width p=25 nm, and this exceeds the manufacturing limitations of a mark with an electronic beam exposure device, for example.

Accordingly, it is desirable to determine k with consideration for the manufacturing limitations of the M-series mark and the measurement range of the imaging sensors. Next, the M-series mark signal f(x) on the imaging side is created after being enlarged with optical magnification from the M-series mark 341A and 341B on the physical object side.

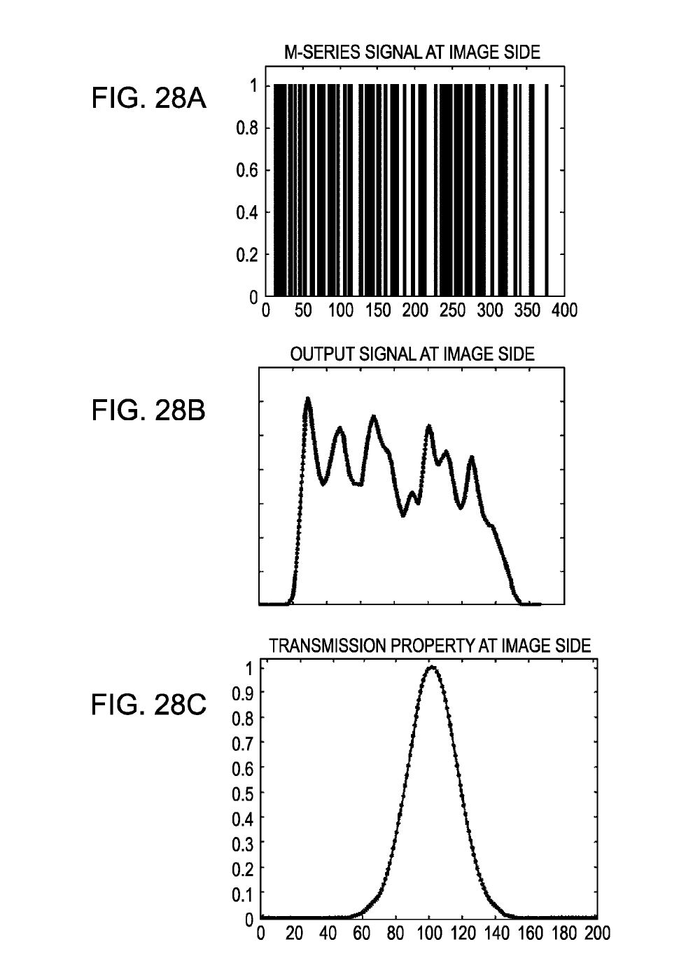

FIG. 28A is an example of the M-series mark signal f(x) on the imaging side wherein, after being enlarged with optical magnification from the M-series mark 341A of a system length 127, the signal is projected in the non-measurement direction (Y-direction) and converted to a one-dimensional signal. However, this is in the case of the above conditions, where k=5, c=8 μm, α=320, and p=125 nm.

FIG. 28B shows the output signal g(x) on the image side wherein the M-series mark 341A projects the mark image that is formed (deteriorated) by the optical system in the non-measurement direction (Y-direction) and converted into a one-dimensional signal.

Next, the transfer characteristic h(x) on the image side is computed from the output signal g(x) on the image side and the M-series mark signal f(x) on the image side. Between the output signal g(x) on the image side, the M-series mark signal f(x) on the image side, and transfer characteristic h(x) on the image side, the relation of

g(x)=f(x)*h(x) (Expression 7)

holds (* denotes convolution). Accordingly, this is subjected to Fourier transform, whereby

FT(g)=FT(f)*FT(h) (Expression 8)

holds. The Fourier transform is denoted here by FT.

In Expression 8, FT(g) and FT(f) are calculated to compute FT(h), and FT(h) is subject to inverse Fourier transform, whereby the transfer characteristic h(x) on the image side is computed.

FIG. 28C is an example of the transfer characteristic on the image side computed with the above-described method.

Next, a determination method of the restoration parameter of the alignment signal according to a first embodiment of the present invention will be described with reference to the flowchart shown in FIG. 1.

First, in step S100, the transfer characteristic of the alignment detecting system 150 is measured beforehand. The measurement method of the transfer characteristic of the alignment detecting system may be a method using the above-described minute slit 350A or a method using the M-series mark 351A or the like.

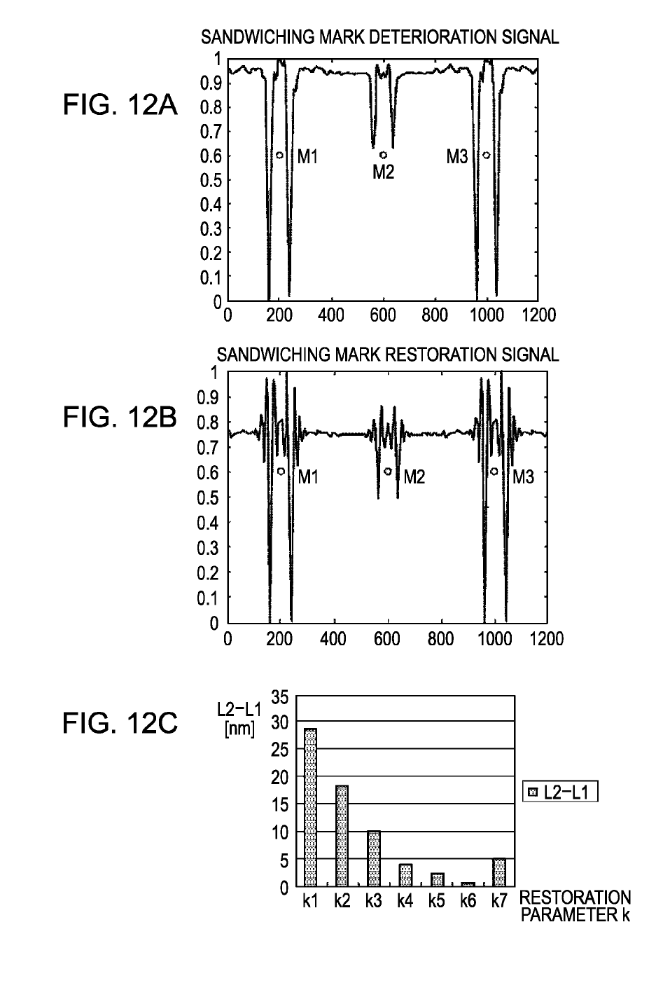

Next, in step S110, the sandwiching mark 350A is used to obtain the mark signal. FIG. 12A shows an example of an obtained signal in the case of d1=200 nm and d2=300 nm. We can see that, compared to the marks M1, M3 on both edges, the mark M2 in the middle has lower contrast. M1 through M3 have been used previously as positions of the mark elements, but can also be used as the names of the mark elements.

Next, in step S120 determination is made as to whether the sandwiching mark signal is restored with all of the restoration parameters, and if not yet restored, in step S130 the restoration parameter is changed and a restoration signal is generated. The restoration method according to the present embodiment employs a Wiener filter.

First, the Wiener filter is set as

$$K = \frac{{FT ( h )}^{⋆}}{{\vert FT ( h ) \vert}^{2} + γ} = \frac{{FT ( h )}^{⋆}}{{\vert FT ( h ) \vert}^{2} + {γ}_{k}} \qquad ( Expression 9 )$$

and the signal of the sandwiching mark 350 is restored while changing the value of γk as the restoration parameter. With the present embodiment, as an example of γk in Expression 9, the case of

γₖ=10^{-k} (Expression 10)

is described.

FIG. 12B shows a restoration signal of a certain restoration parameter (k=k4).

Next, in step S140, the mark position of the sandwiching mark 350A is measured. The mark position detecting method according to the present embodiment uses symmetry pattern matching. If we say that the signal subject to processing is y(x), the window center of the signal processing is c, and the window width is w, the symmetry matching rate S(x) is expressed in Expression 11.

$$S ( x ) = {\sum }_{i = C - \frac{W}{2}}^{C + \frac{W}{2}} \vert y ( x - i ) - y ( x + i ) \vert \qquad ( Expression 11 )$$

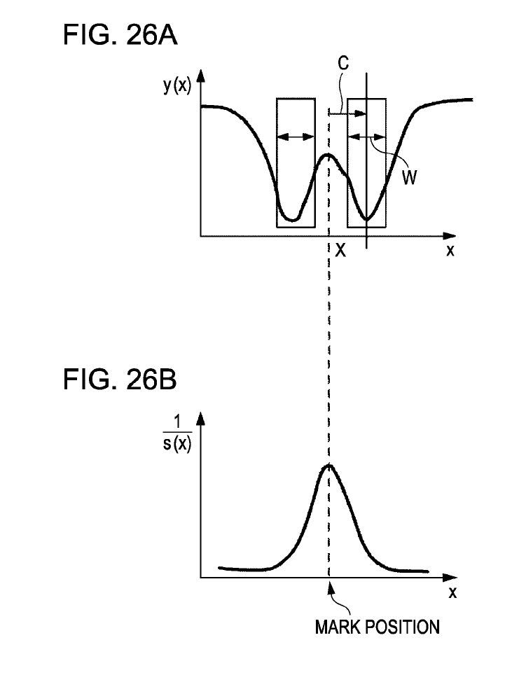

In the case of setting the extreme value of S(x) as the mark center position, the S(x) at a given point X is obtained from Expression 10, and S(x) is obtained while continuously changing x, as shown in FIG. 26A. A sub-pixel position serving as the minimum (smallest) of S(x) or the maximum (largest) of 1/S(x) shown in FIG. 26B, are subject to function fitting, whereby the mark position is computed. The mark position computing results M1, M2, and M3 are thus obtained. In FIGS. 12A and 12B, ◯ denotes the positions of M1, M2, and M3.

Lastly in step S150, the mark position spacing L2−L1 is obtained, and an optimal restoration parameter is determined.

FIG. 12C is a diagram to describe a method to determine the optimal restoration parameter, and shows L2−L1 as to various restoration parameters. Referencing FIG. 12C, when k=k6, the L2−L1 is smallest, whereby this is determined as the parameter used for restoring the alignment signal according to the present embodiment.

According to a second embodiment according to the present invention, a method to determine the optimal restoration parameter is based on multiple mark position measurement values. A feature of the second embodiment is to change the processing window for symmetry pattern matching in order to obtain multiple mark position measurement values.

As opposed to a signal that is distorted asymmetrically by comatic aberration or the like of the alignment detecting system, a restored signal is desirable that is a signal as symmetrical as possible. A parameter having a small change in the mark position spacing L2−L1 (high robustness) as to the processing window changes of the symmetry pattern matching is used.

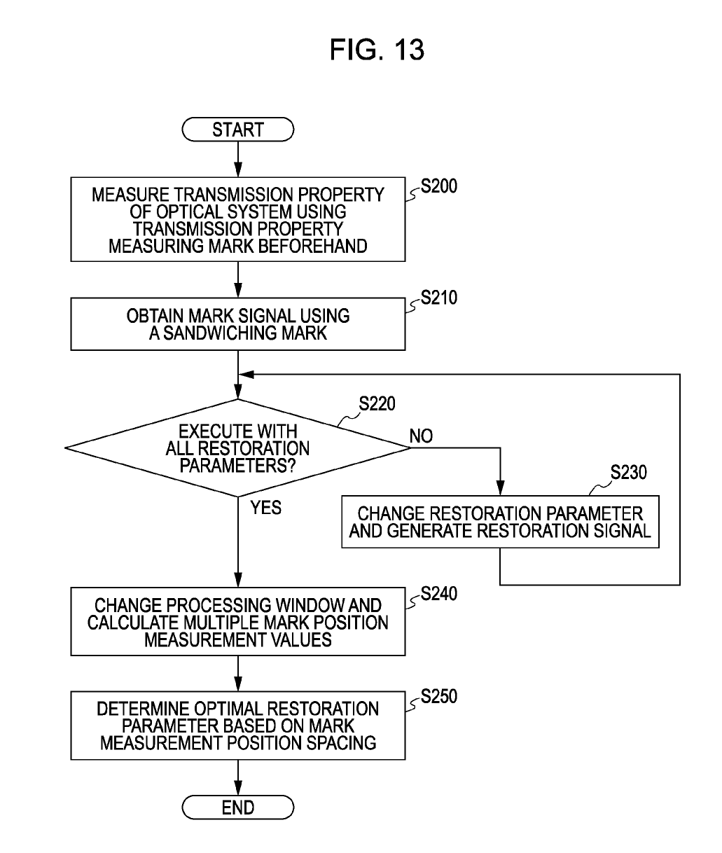

FIG. 13 is a flowchart describing the second embodiment. In step S200, similar to the first embodiment, the transfer characteristic of the alignment detecting system 150 are measured beforehand, and the mark signal is obtained using a sandwiching mark in step S210.

Next, in step S220, until the mark signal is restored with all of the restoration parameters, the restoration parameters are changed in step S230, and a restoration signal is generated. The difference of the second embodiment from the first embodiment is that in the next step S240, the symmetry pattern matching processing window is changed and multiple mark positions are calculated. Changing the processing window means specifically to change c or w in Expression 6.

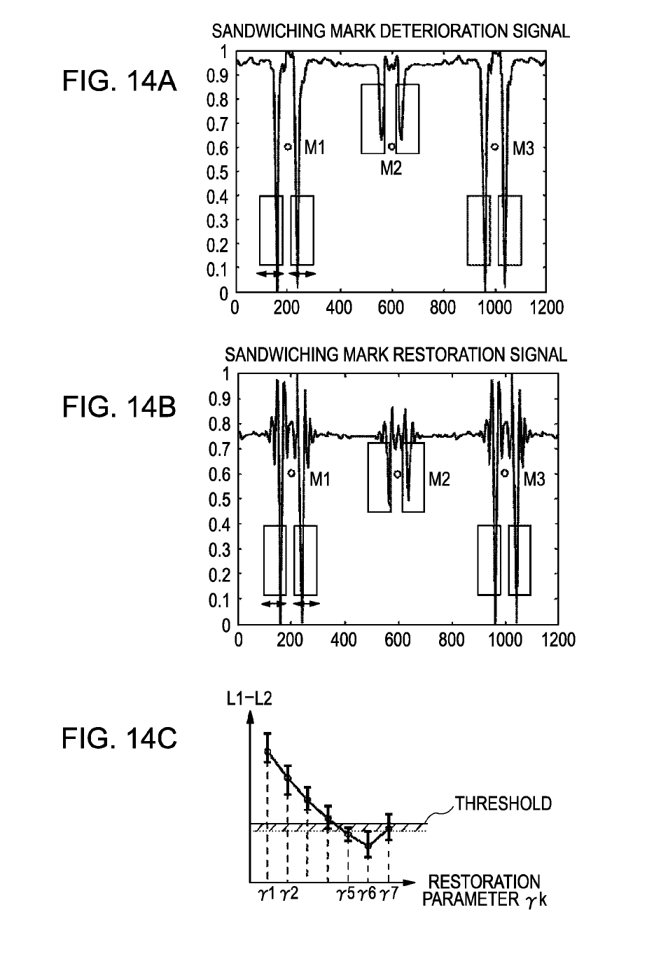

FIG. 14A shows a sandwiching mark signal at certain processing windows, wherein the processing windows are surrounded with a quadrangle. Also, FIG. 14B shows a restoration signal that is restored with a certain restoration parameter, and similarly shows the processing windows.

FIG. 14C is a diagram plotting the mark element spacing difference L2−L1 as to a restoration parameter, and by changing the processing window, the mark element spacing difference L2−L1 can be seen as scattered within the range shown by the bars in the diagram.

With the second embodiment according to the present invention, with the determining method for the restoration parameter in the next step S250, a restoration parameter is selected wherein an average value of the multiple mark position spacing differences L1−L2 is smaller than a predetermined threshold and the scattering (e.g. variance or standard deviation) of the difference L1−L2 is small. That is to say, γ5 in FIG. 14C is selected as the restoration parameter. Now, the predetermined threshold is set to be within the range permitted by the error (TIS) of the alignment detecting system, and preferably should be a value of at least 1 nm or less.

The present embodiment describes a determining method of the restoration parameter with consideration for both the average value and scattering, but the method should not be limited to this, and a parameter may be selected without an average value and only with scattering (e.g. to provide minimal scattering). In FIG. 14C, γ5 may be a parameter providing minimum scattering.

Also, with the present embodiment, multiple processing windows are used. But the present invention is not limited to this. For example, any of multiple commonly-known signal processing conditions to detect the alignment mark position from the detecting signal can alternatively be applied. The multiple signal processing conditions may be multiple types of signal processing algorithms, or may be multiple parameters with an identified signal processing algorithm.

In order to obtain multiple mark positions, a third embodiment of the present invention features using multiple types of sandwiching marks formed on an Si wafer 131, rather than using multiple types of processing windows as in the second embodiment.

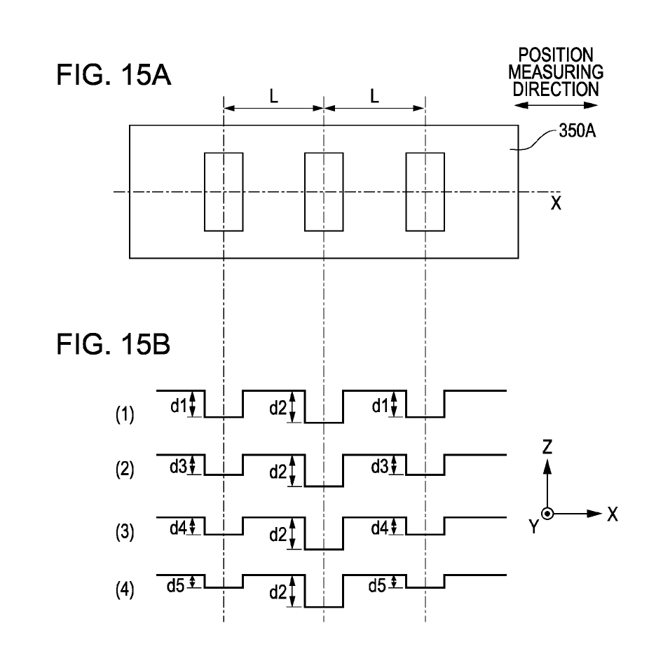

FIG. 15B is a cross-sectional diagram in the case of variously changing the step dimension of the sandwiching marks, and the step dimension d1 of the sandwiching marks M1 and M3 with the first embodiment is changed to d3, d4, d5, which is then formed on the Si wafer 131.

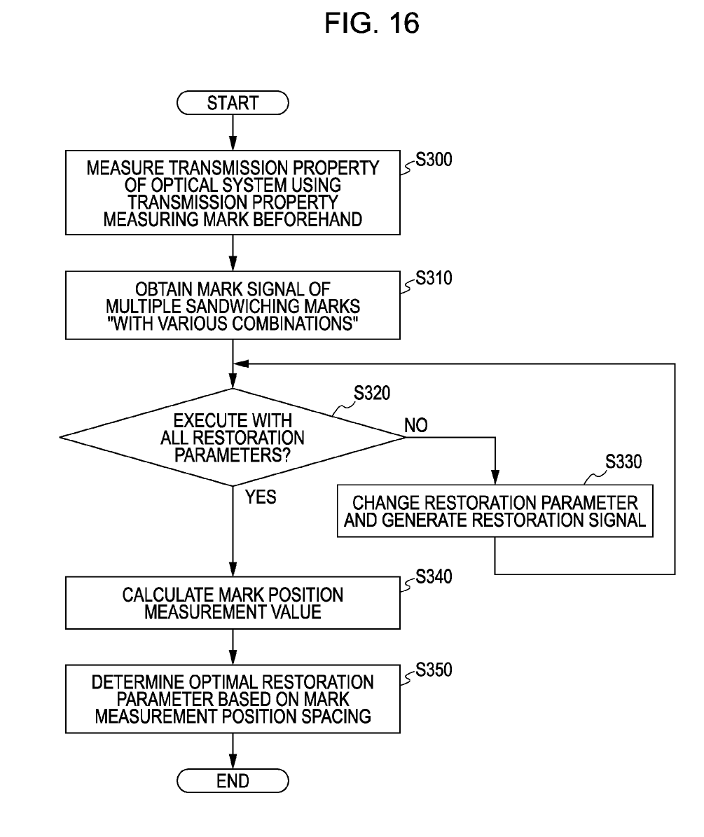

FIG. 16 is a flowchart describing the third embodiment. In step S300, the transfer characteristic of the alignment detecting system 150 are measured beforehand.

The difference from the second embodiment is that in step S310, a mark signal with multiple sandwiching marks made up of various combinations of step dimensions (in this case, four types of (1) through (4)) is obtained.

Next, in step S320 until the sandwiching mark signal is restored with all of the restoration parameters, the restoration parameters are changed in step S330, a restoration signal is generated, and the mark position measurement value is calculated for the multiple sandwiching mark signal from (1) through (4) in step S340.

With the third embodiment, similar to the second embodiment, with the determining method of the restoration parameter in step S350, a restoration parameter is selecting which has an average of mark position spacing differences L1 L2 that is smaller than the predetermined threshold, and which has minimal scattering of the difference L1−L2.

In order to obtain multiple mark measurement positions, a fourth embodiment of the present invention features using one sandwiching mark and obtaining multiple sandwiching mark signals by shifting the stage position thereof at sub-pixel precision.

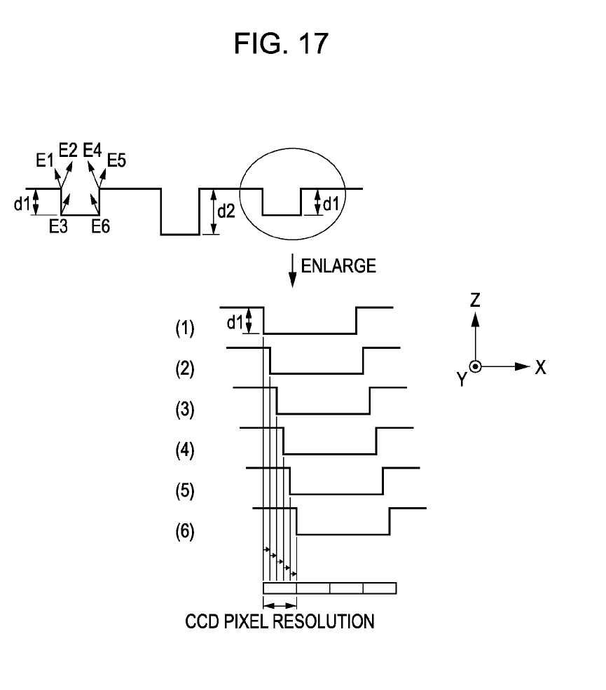

FIG. 17 is a diagram describing the fourth embodiment of the present invention, and shows one mark of the sandwiching mark 350 enlarged.

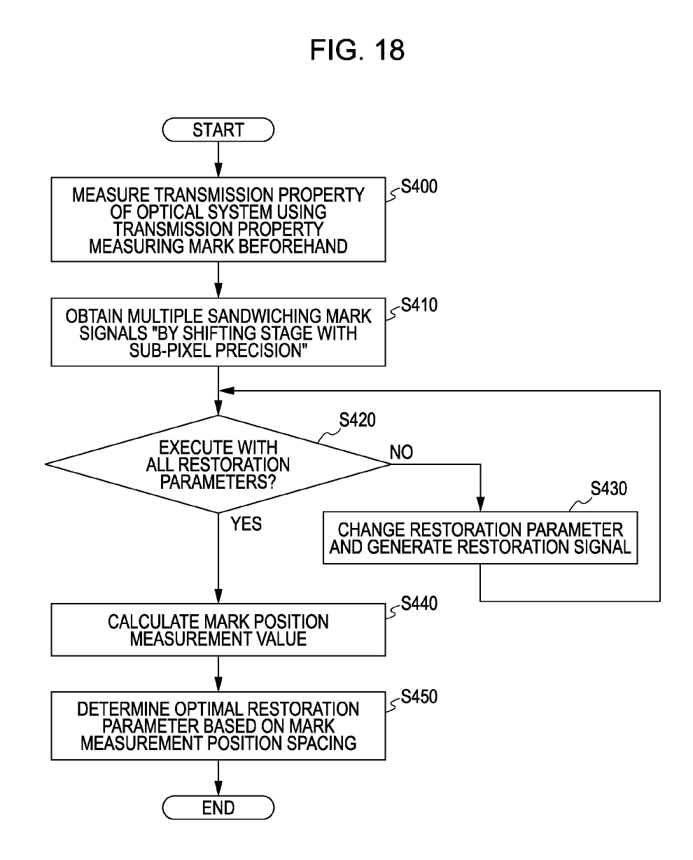

FIG. 18 is a flowchart describing the fourth embodiment, wherein the transfer characteristic of the alignment detecting system 150 is measured beforehand in step S400.

The difference from the third embodiment is that in step S410, the stage position is shifted at sub-pixel precision to obtain multiple sandwiching mark signals. For example, if the pixel resolution on a physical object of an imaging sensor such as the CCD is 50 nm/pix, with a stage 140 having a laser interferometer, the stage position is shifted in 10 nm pitch in the measurement direction (X-direction), and the sandwiching mark signal is obtained each time. Thus, multiple sandwiching mark signals from (1) through (6) can be obtained.

Next, in step S420 until the sandwiching mark signal is restored with all of the restoration parameters, the restoration parameters are changed in step S430, a restoration signal is generated, and the mark position measurement value is calculated for the multiple sandwiching mark signals from (1) through (6) in step S440.

In the next step S450, a restoration parameter should be selected wherein the average of the mark position spacing difference L1−L2 is smaller than a predetermined threshold value, and wherein scattering of the difference L1−L2 is minimal. The present embodiment beneficially provides a restoration parameter with high robustness as to the error occurring from the resolution of the imaging sensor such as a CCD.

In order to obtain multiple sandwiching mark signals, the fifth embodiment of the present invention features using multiple marks having different thicknesses of resist film.

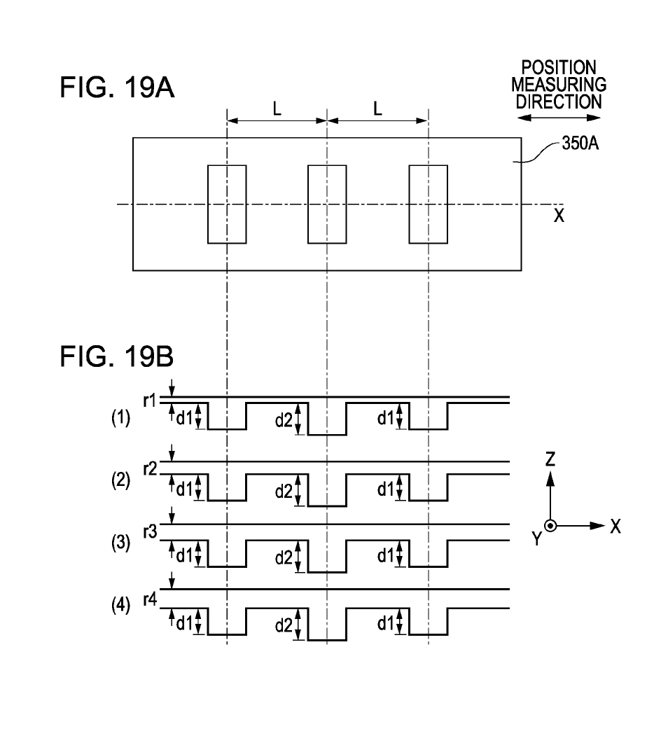

FIGS. 19A and 19B are diagrams describing the fifth embodiment of the present invention, and FIG. 19A shows a plan view of the sandwiching mark 350A while FIG. 19B shows a cross-sectional view thereof. Referencing FIG. 19B, with the four marks (1) through (4), the step dimension of the three mark elements are the same wherein M1 and M3 are d1 and M2 is d2, but on both edges of the diagram the resist film thickness differs from r1 to r4.

When the resist film thus differs, the mark elements M1, M2, and M3 respectively differ in asymmetry of the image from the TIS of the alignment detecting system, whereby the mark element spacing differences L2−L1 as to the four marks (1) through (4) are not the same, but rather scattering occurs.

Accordingly, similar to the step S350 in the third embodiment, a restoration parameter should be selected wherein the average of the mark element spacing differences L2−L1 is smaller than a predetermined threshold, and wherein scattering of the differences L2−L1 is minimal.

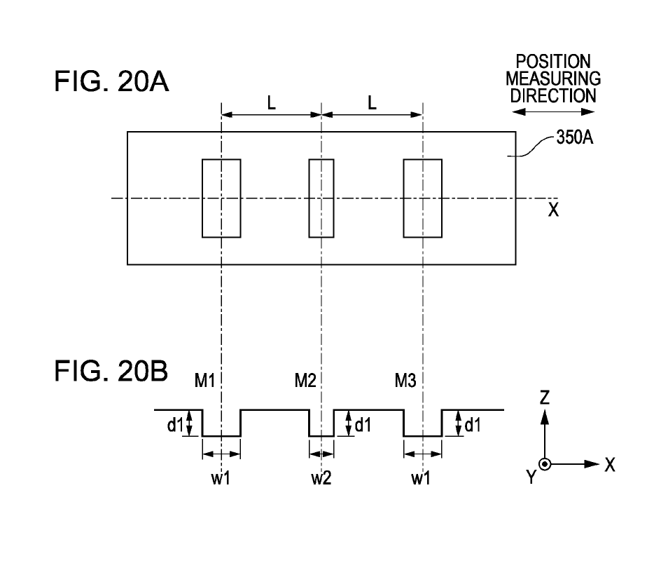

A sixth embodiment of the present invention uses marks having different line widths instead of step dimensions. FIGS. 20A and 20B are diagrams describing the sixth embodiment of the present invention, and FIG. 20A shows a plan view of the sandwiching mark 350A while FIG. 20B shows a cross-sectional view thereof. The step dimension for three mark elements are the same at d1, but the line width is w1 for the marks M1 and M3 on both edges whereas the mark M2 in the middle differs at w2. When the line width differs, the image asymmetry for the mark M2 differs as to the marks M1 and M3 from the TIS of the alignment detecting system, whereas the mark element spacing difference l2−L1 does not become zero.

Accordingly, similar to the step S150 described with the first embodiment of the present invention, a restoration parameter should be selected wherein the mark element spacing difference L2−L1 is minimal.

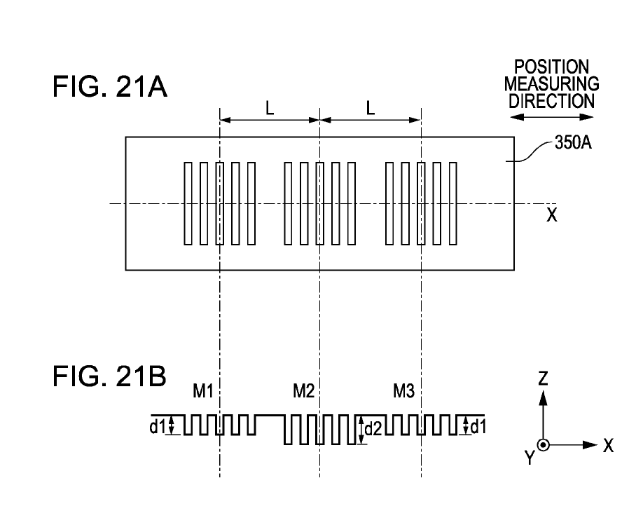

According to a seventh embodiment of the present invention, the mark element described with respect to the first embodiment is modified to include multiple mark elements. FIGS. 21A and 21B are diagrams describing the seventh embodiment of the present invention, and FIG. 21A shows a plan view of the sandwiching mark 350A while FIG. 21B shows a cross-sectional view thereof.

Referencing FIG. 21B, the mark elements M1, M2, and M3 each include five mark element, and the step dimension differs with M1 and M3 at d1 and M2 at d2. For example, in the event in measuring the position of the mark element M1, the average value of each position of the five mark elements can be used.

According to the present embodiment, an averaging effect to obtain the positions of the various mark elements M1, M2, and M3 can be expected, whereby measurement precision of the mark element spacing difference L2−L1 can be improved. Thus, the determining precision of restoration parameters can be improved.

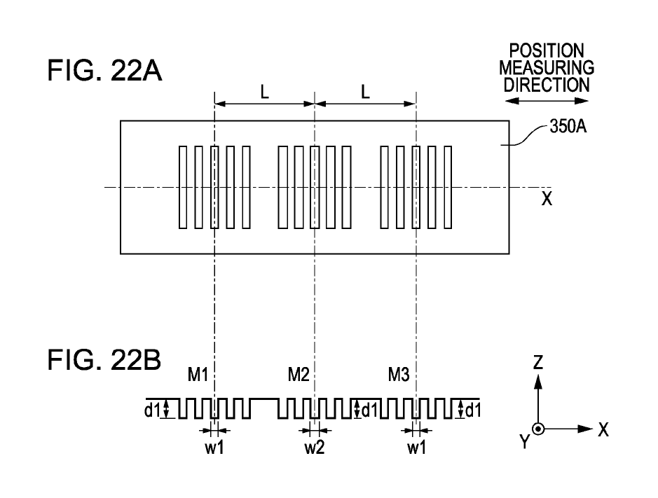

According to an eighth embodiment of the present invention, the mark elements described in the sixth embodiment are modified to include multiple mark elements. FIGS. 22A and 22B are diagrams describing the eighth embodiment of the present invention, and FIG. 22A shows a plan view of the sandwiching mark 350A while FIG. 22B shows a cross-sectional view thereof.

Referencing FIG. 22B, the mark elements M1, M2, and M3 each include five mark elements, and the line widths differ with M1 and M3 at w1, and M2 at w2. For example, in the event of measuring the position of the mark element M1, an average value of each of the five mark elements thereof is used.

With the present embodiment, an averaging effect to measure the positions of the various mark elements M1, M2, and M3 can be expected, whereby measurement precision of the mark element spacing difference L2−L1 can be improved. Thus, the determining precision of restoration parameters can be improved.

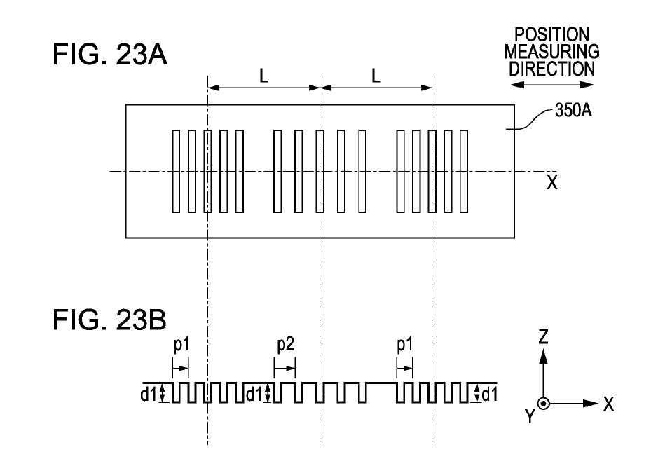

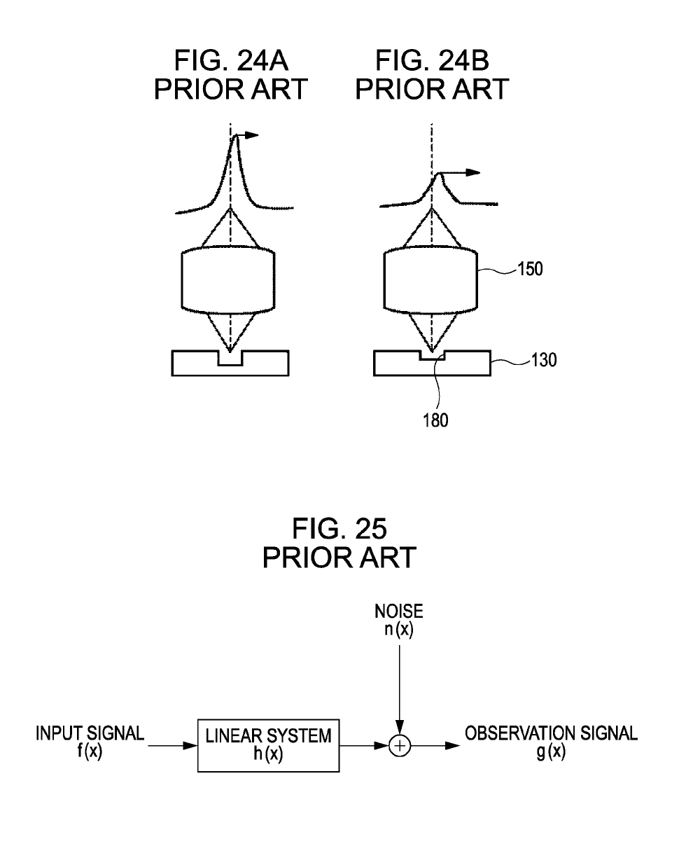

According to a ninth embodiment of the present invention, pitch of the mark elements further within the mark elements differs. FIGS. 23A and 23B are diagrams describing the ninth embodiment of the present invention, and FIG. 23A shows a plan view of the sandwiching mark 350A while FIG. 23B shows a cross-sectional view thereof.

Referencing FIG. 23B, the mark elements M1, M2, and M3 each include five mark elements, and while the line widths are the same, the pitch differs with M1 and M3 at p1, and M2 at p2. When the pitch thus differs, the mark element within the mark M2 differ in image asymmetry with the TIS of the alignment detecting system, as to the mark elements within the marks M1 and M3. Thus, the mark element spacing L2−L1 obtained using the average value of positions of each of the five mark elements does not become zero.

Accordingly, similar to the step S150 described with the first embodiment, a restoration parameter should be selected wherein the mark element spacing difference L2−L1 is minimal.

The restoration parameters described with the embodiments up to this point have been a parameter γ of a Wiener filter such as shown in Expression 9, but the present invention is not be limited to this. For example, the parameter α of the parametric Wiener filter shown in Expression 12 may be used as the restoration parameter. The parameter α is a coefficient as to Sn/Sf, and Sn/Sf at this time may be either a known value or a fixed value.

$$K = \frac{{fft ( h )}^{⋆}}{{\vert fft ( h ) \vert}^{2} + α \cdot Sn / Sf} \qquad ( Expression 12 )$$

Also, the above-described Wiener filter and parametric Wiener filter obtain the optimal restoration signal in the sense of an average as to a collection of input signals. Conversely, the present invention may be applied to a projection filter having a feature of obtaining the optimal restoration signal as to individual input signals. Particularly, a parametric projection filter is a restoration filter which greatly reduces the influence of noise by sacrificing restoration quality of the signal components slightly with the parameter.

Next, a case wherein a parameter of a parametric projection filter is applied to a restoration parameter will be described. Expressing the input/output relation in FIG. 25 with a vector-matrix expression can be shown as in Expression 13.

g=H·f+n (Expression 13)

Now, with the input signal f and observation signal g as an N-dimensional vector, H is expressed as the circulant matrix of N×N shown in Expression 14.

$$H = [ \begin{matrix}h ( 0 ) & h ( N - 1 ) & … & h ( 1 ) \\ h ( 1 ) & h ( 0 ) & … & h ( 2 ) \\ ⋮ & ⋮ & ⋮ & ⋮ \\ h ( N - 1 ) & h ( N - 2 ) & … & h ( 0 )\end{matrix} ] \qquad ( Expression 14 )$$

At this time, the input signal f′ to be restored is expressed as in Expression 15.

f′=K·g (Expression 15)

Now, K is a parametric projection filter, and specifically is expressed as in Expression 16, whereby the present invention can be applied with the parameter β in this expression as a restoration parameter.

K=H*(HH*+β·R_{z})⁺ (Expression 16)

Now, * denotes a conjugate transposed matrix, and + denotes a pseudo inverse matrix. Rz is a correlation matrix for noise z, and is expressed as in Expression 17. Ez is an ensemble mean relating to noise. Moreover, β is a coefficient as to Rz, and since β is a parameter, Rz measures other noise and is either a known value or a fixed value.

R_{z}=E_{z}(zz*) (Expression 17)

Next, a manufacturing method of a device (semiconductor device, liquid crystal display device, etc.) according to an embodiment of the present invention will be described. With this method, the exposure apparatus applying the present invention can be used.

A semiconductor device is manufactured through a pre-processing to create an integrated circuit on a wafer (semiconductor substrate), and a post-process to complete the integrated circuit chip on the wafer created with the pre-process as a product. The pre-process may include a process to use the above-described exposure apparatus to expose the wafer on which a photosensitive material is coated, and a process to develop the wafer exposed with such process. The post-process may include an assembly process (dicing, bonding) and a packaging process. Also, the liquid crystal display device is manufactured via a process to form a transparent electrode. The process to form the transparent electrode may include a process to coat photosensitive material onto a glass substrate whereupon a transparent conductive film is vapor-deposited, a process to expose the glass substrate on which the photosensitive material is coated, using the above-described exposure apparatus, and a process to develop the glass substrate exposed with such process.

The device manufacturing method according to the present embodiment is believed to advantageously provide higher device productivity, higher quality, and lower production cost than conventional techniques.

Various embodiments of the present invention are described above, but the present invention is not limited to these embodiment, and a wide variety of forms and modifications may be made within the sprit and scope of the invention.

For example, since transfer characteristic of a detection apparatus (alignment detecting system) can change, the transfer characteristic of the detecting apparatus are measured and updated at time of periodic maintenance, whereby performing signal restoration of the present invention using the updated transfer characteristic can enable position detecting with higher precision.

Also, if aberration such as comatic aberration exists on the optical system, the detection signal can greatly distort from the interactions between the process error (WIS) of the alignment mark configuration, causing position detection errors of the alignment marks. With such a case also, according to the above embodiments, position detecting of the alignment marks may be performed as to a detection signal which is restored using transfer characteristic of an alignment detecting system, thus enabling high precision alignment.

While the present invention has been described with reference to various exemplary embodiments, it is to be understood that the invention is not limited to the disclosed exemplary embodiments. The scope of the following claims is to be accorded the broadest interpretation so as to encompass all modifications and equivalent structures and functions.

This application claims the benefit of Japanese Patent Application No. 2008-050128 filed Feb. 29, 2008, which is hereby incorporated by reference herein in its entirety.

What is claimed is:

1. A detecting apparatus comprising:
a image pickup device configured to supply an output signal;
an imaging optical system configured to form an image of an alignment mark formed on a substrate onto the image pickup device; and
a signal processing unit including a restoration filter having a parameter that can be set, and configured to process the output signal and detect a position of the alignment mark, wherein the signal processing unit is configured to
cause the restoration filter to act upon the output signal and generate a restoration signal;
compute based on the restoration signal, for each of a plurality of candidate values of the parameter, a corresponding feature value relating to a form of the alignment mark; and
set the parameter based on the computed feature values.

2. An apparatus according to claim 1, wherein the corresponding feature value relates to a symmetry of the alignment mark in a direction of detecting the position of the alignment mark.

3. An apparatus according to claim 1, wherein the corresponding feature value relates to one of scattering of a size of a plurality of elements of the alignment mark in a direction of detecting the position of the alignment mark and scattering of a symmetry of the plurality of elements in the direction of detecting the position of the alignment mark.

4. An apparatus according to claim 1, wherein the corresponding feature value relates to a spacing of a plurality of elements of the alignment mark in a direction of detecting the position of the alignment mark.

5. An apparatus according to claim 4, wherein the plurality of elements have one of a differing plurality of step dimensions, a plurality of size differing in the direction of detecting the position of the alignment mark, and a plurality of spacing differing in the direction of detecting the position of the alignment mark.

6. An apparatus according to claim 1, wherein the signal processing unit is configured to computes a feature value for each of a plurality of signal processing conditions and set the parameter based on scattering of the computed feature values.

7. An apparatus according to claim 1, wherein the signal processing unit is configured to compute a feature value for each of one of a plurality of types of the alignment mark, a plurality of positions of the substrate, and a plurality of resist film thicknesses, and set the parameter based on scattering of the computed feature values.

8. An apparatus according to claim 6, wherein the signal processing unit is configured to set the parameter such that the scattering is minimal.

9. An apparatus according to claim 4, wherein the corresponding feature value includes a difference between two of the spacing.

10. An apparatus according to claim 9, wherein the signal processing unit is configured to set the parameter such that the difference is minimized.

11. An apparatus according to claim 6, wherein the corresponding feature value includes a differences between two of the spacing, and wherein the signal processing unit is configured to set the parameter such that the difference of the spacing is smaller than a threshold and such that the scattering is minimal.

12. An apparatus according to claim 1, wherein the restoration filter includes at least one of a Wiener filter, a parametric Weiner filter, and a parametric projection filter.

13. An apparatus according to claim 12, wherein the parameter relates to noise.

14. An apparatus according to claim 13, wherein the restoration filter includes a Wiener filter, and wherein the parameter reflects a ratio between a power spectrum of noise and a power spectrum of an input signal of the imaging optical system.

15. An apparatus according to claim 13, wherein the restoration filter includes a parametric Wiener filter, and wherein the parameter includes a coefficient as to a ratio between a power spectrum of noise and a power spectrum of an input signal of the imaging optical system.

16. An apparatus according to claim 13, wherein the restoration filter includes a parametric projection filter, and wherein the parameter includes a coefficient as to a correlation matrix of noise.

17. An exposure apparatus comprising:
a substrate stage configured to hold a substrate and to be moved;
a controller configured to control the position of the substrate stage based on a position of at least one alignment mark formed on the substrate held by the substrate stage, the exposure apparatus exposing the substrate, held by the substrate stage of which position is controlled by the controller, to radiant energy; and
a detecting apparatus according to claim 1 and configured to detect the position of the at least one alignment mark.

18. A method of manufacturing a device, the method comprising:
exposing a substrate to radiant energy using the exposure apparatus of claim 17;
developing the exposed substrate; and
processing the developed substrate to manufacture the device.
